(19) United States
(12) Patent Application Publication
(10) Pub. No.: US 2009/0098702 A1
(43) Pub. Date: Apr. 16, 2009

(54) Method to Form CMOS Circuits Using Optimized Sidewalls

(75) Inventors: Brian K. Kirkpatrick, Allen, TX (US); Weize Xiong, Plano, TX (US); Steven L. Prins, Fairview, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/253,095

(22) Filed: Oct. 16, 2008

Related U.S. Application Data
(60) Provisional application No. 60/980,347, filed on Oct. 16, 2007.

(51) Int. Cl. H01L 21/336; H01L 21/762

(52) U.S. Cl. 438/296; 438/425; 257/E21.409; 257/E21.546

(57) ABSTRACT

A method of forming reduced width STI field oxide elements using sidewall spacers on the isolation hardmask to reduce the STI trench width is disclosed. The isolation sidewall spacers are formed by depositing a conformal layer of spacer material on the isolation hardmask and performing an anisotropic etch. The isolation sidewall spacers reduce the exposed substrate width during the subsequent STI trench etch process, leading to a reduced STI trench width. A method of forming the isolation sidewall spacers of a material that is easily removed from the isolation hardmask to provide an exposed shoulder width on the substrate defined by the sidewall thickness is also disclosed.

### FIELD OF THE INVENTION

This invention relates to the field of integrated circuits. More particularly, this invention relates to methods to improve shallow trench isolation.

### BACKGROUND OF THE INVENTION

It is well known that lateral dimensions of components in advanced complementary metal oxide semiconductor (CMOS) integrated circuits (ICs) are shrinking with each new fabrication technology node, as articulated by Moore's Law. Transistors in CMOS ICs are electrically isolated from each other by elements of field oxide formed by shallow trench isolation (STI) processes. In dense circuits such as static random access memories (SRAMs), it is desirable to have a width ratio of silicon to field oxide above 0.85:1. Photolithographic processes available during each fabrication technology node are typically capable of printing lines and spaces at the pitch (total width of one line and one space) of the dense circuits with approximately 1:1 width ratios. STI processes include etches and oxidation operations which typically consume 10 nanometers or more of silicon on each side of an element of field oxide, undesirably reducing the silicon to field oxide ratio below an optimum value for circuit performance. Fabricating dense circuits at the 45 nanometer node and beyond becomes increasingly difficult due to conflicting constraints between photolithographic and STI processes.

Accordingly, a field oxide fabrication process which can attain a silicon to field oxide ratio between 0.85:1 and 1:1 at a pitch of less than 100 nanometers is desired.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

The instant invention provides a method of forming STI field oxide with reduced trench width by forming isolation sidewall spacers on the isolation hard mask prior to etching STI trenches. The isolation sidewall spacers are formed by depositing a conformal layer of spacer material on the isolation hardmask and performing an anisotropic etch which removes spacer material from horizontal surfaces and leaves the desired spacers on lateral surfaces of the isolation hardmask. The isolation sidewall spacers reduce the exposed substrate width during the subsequent STI trench etch process, leading to a reduced STI trench width. Furthermore, the isolation sidewall spacers may be composed of a material that is easily removed from the isolation hardmask without removing hardmask material, which provides a more controllable exposed shoulder width on the substrate during subsequent oxidation.

An advantage of the instant invention is that dense areas of active regions and STI field oxide elements may be formed with commonly available CMOS processes which have substrate to STI width ratios between 0.85:1 and 1:1 at a pitch of less than 100 nanometers.

### DESCRIPTION OF THE VIEWS OF THE DRAWING

FIG. 1A through FIG. 1G are cross-sections of a dense circuit region in an IC with field oxide elements formed by STI processes according to a first embodiment of the instant invention.

FIG. 2A through FIG. 2G cross-sections of a dense circuit region in an IC with field oxide elements formed by STI processes according to a second embodiment of the instant invention.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

The need for a field oxide fabrication process which can attain a silicon to field oxide ratio between 0.85:1 and 1:1 at a pitch of less than 100 nanometers is addressed by the instant invention, which provides a sidewall element on an shallow trench isolation (STI) trench etch hardmask to reduce a width of the STI trench etched in the silicon. A further advantage is realized by forming the sidewall element from a material that is easily removed prior to filling the trench with dielectric material.

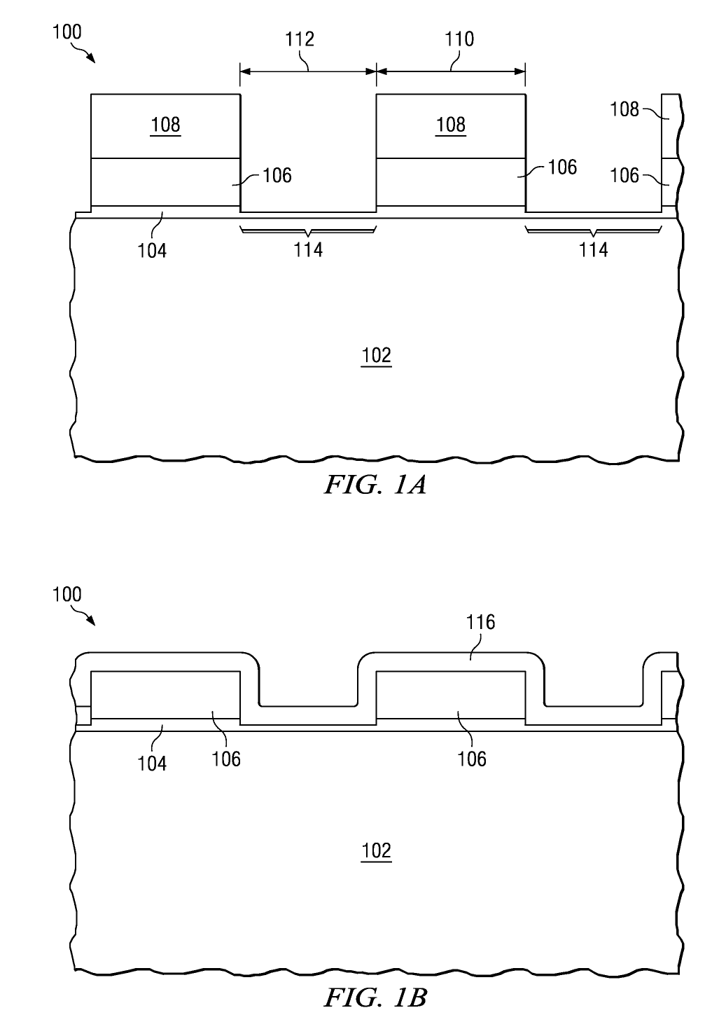

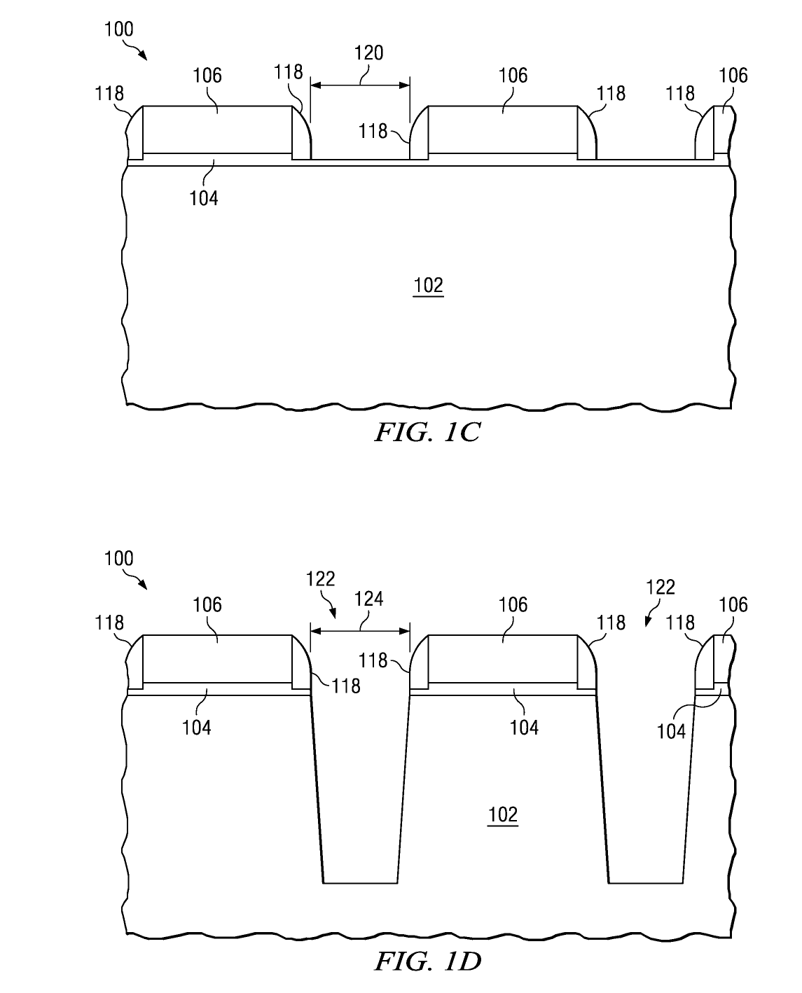

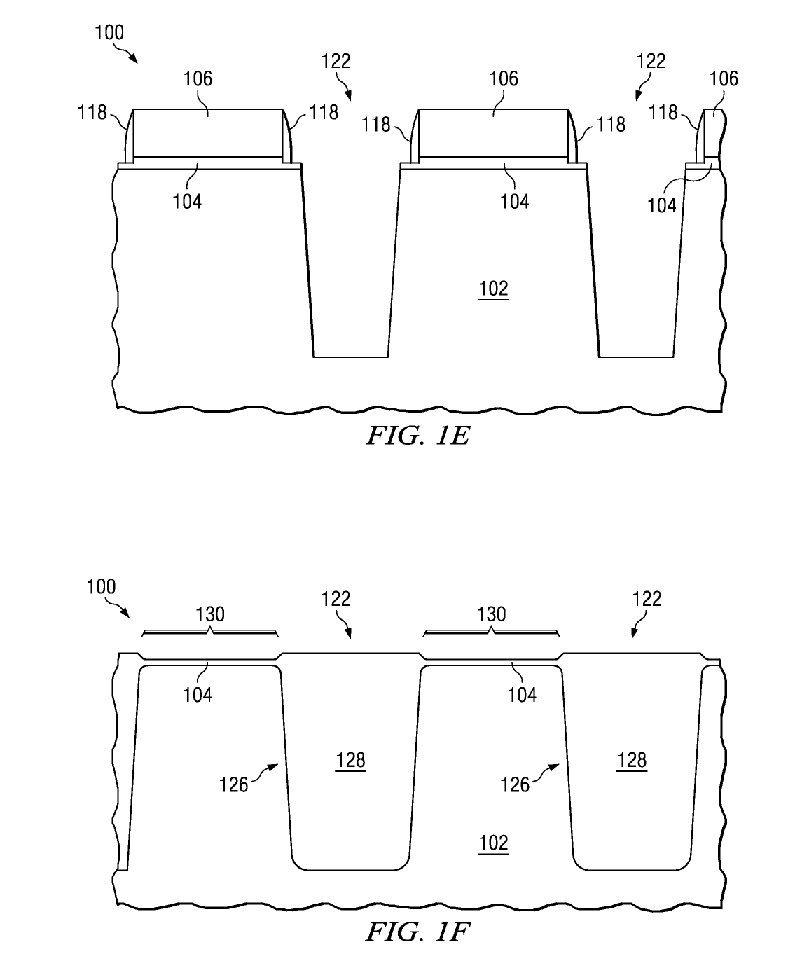

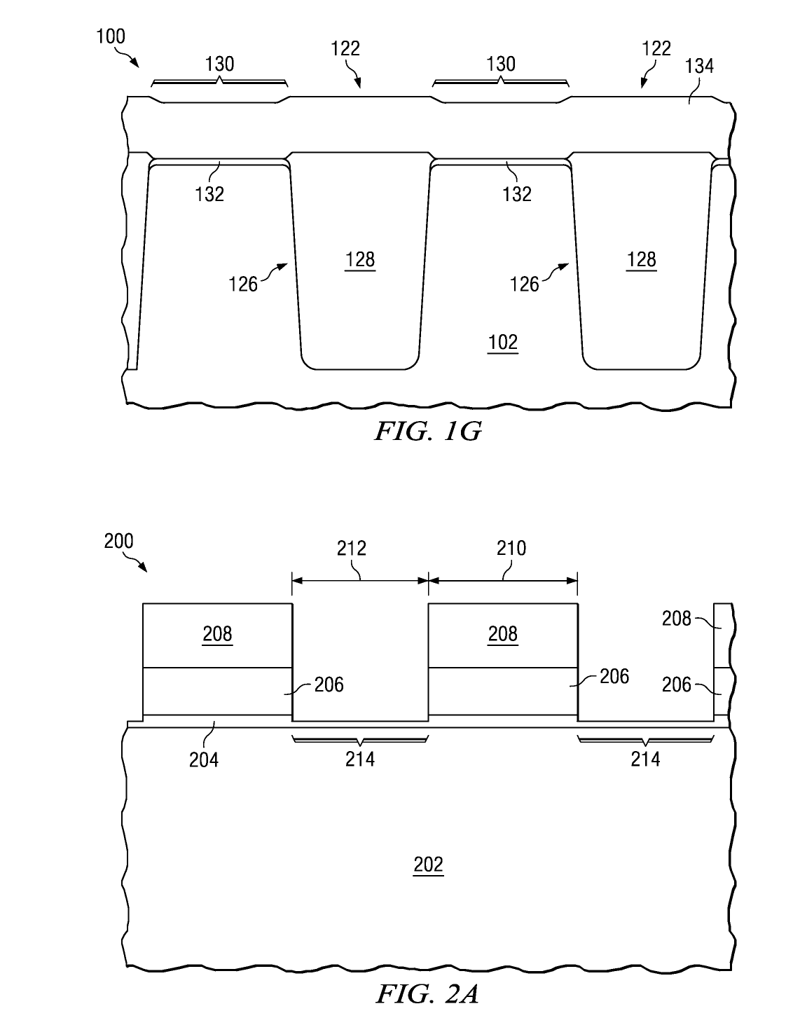

FIG. 1A through FIG. 1G are cross-sections of a dense circuit region in an IC with field oxide elements formed by STI processes according to a first embodiment of the instant invention. Referring to FIG. 1A, the IC (100) is fabricated in a semiconductor substrate (102), typically single crystal silicon or single crystal silicon-germanium, but possibly a hybrid orientation technology substrate or another semiconductor material. An isolation pad layer (104), typically thermally grown silicon dioxide between 2 and 40 nanometers thick, is formed on a top surface of the substrate (102). It is within the scope of the instant invention to form the isolation pad layer (104) of other materials at other thicknesses and by other processes. An isolation hardmask layer (106), typically silicon nitride between 50 and 200 nanometers thick, and commonly deposited by low pressure chemical vapor deposition (LPCVD) or plasma enhanced chemical vapor deposition (PECVD) processes, is formed on a top surface of the isolation pad layer (104). An isolation photoresist pattern (108) is formed on a top surface of the isolation hardmask layer (106) using known photolithographic methods, in which a photoresist line width (110) is between 100% and 115% of a space width (112). STI regions (114) for forming trenches in the substrate (102) are exposed by the isolation photoresist pattern (108). Hardmask material in the isolation hardmask layer (106) is removed in the STI regions (114) by known etching methods, including reactive ion etching (RIE) using fluorine containing plasmas. A portion of the isolation pad layer (104) may be removed in the STI regions (114) during the hardmask etch process. The isolation photoresist pattern (108) is removed for subsequent processing, commonly by exposing the IC (100) to an oxygen containing plasma, followed by a wet cleanup to remove any organic residue from the top surface of the isolation hardmask layer (106).

FIG. 1B depicts the IC (100) after deposition of an isolation conformal sidewall layer (116) on the top surface and lateral surfaces of the etched isolation hardmask layer (106) and the isolation pad layer (104). The isolation conformal sidewall layer (116) is preferably silicon nitride, and is preferably deposited by known LPCVD or PECVD methods, but is possibly another material that is easily removed in subsequent processing. A thickness of the isolation conformal sidewall layer (116) preferably is between 2 and 9 nanometers, and is prescribed by a target thickness of an isolation sidewall spacer formed from the isolation conformal sidewall layer (116) by subsequent processing. For example, to obtain a 5 nanometer thickness of an isolation sidewall spacer, it may be necessary to deposit 6.5 nanometers of sidewall material in the isolation conformal sidewall layer (116).

FIG. 1C depicts the IC (100) after a sidewall anisotropic etch process removes isolation conformal sidewall material from a top surface of the etched isolation hardmask layer (106) and a top surface of the isolation pad layer (104) to form isolation sidewall spacers (118) on lateral surfaces of the etched isolation hardmask layer (106). The sidewall anisotropic etch process is performed using known RIE methods. A horizontal thickness of the isolation sidewall spacers (118) is preferably between 2 and 7 nanometers, and is a function of the thickness of the isolation conformal sidewall layer and the sidewall anisotropic etch process. An exposed width (120) of the isolation pad layer (104) is desirably less than the space width (112) of the isolation photoresist pattern (108) described above in reference to FIG. 1A.

FIG. 1D depicts the IC (100) after an STI trench etch process removes substrate material to form STI trenches (122) in the substrate (102). The STI trenches (122) are 125 to 400 nanometers deep, depending on the transistors that will be formed in adjacent substrate regions. An STI trench top width (124) is substantially equal to the exposed width (120) of the isolation pad layer (104) described in reference to FIG. 1C, such that any difference is due to details of the STI trench etch process.

FIG. 1E depicts the IC (100) after a hardmask pullback process in which a portion of the etched isolation hardmask layer (106) and a portion of the isolation sidewall spacers (118) are removed. The hardmask pullback process is preferably more isotropic than the sidewall anisotropic etch process. The hardmask pullback process may be performed using wet chemicals such as phosphoric acid or by an isotropic plasma etch. In an alternate embodiment, the isolation sidewall spacers (118) may be completely removed during the hardmask pullback process. One purpose of the hardmask pullback process is to reduce voids in a subsequent STI fill operation in which dielectric material is deposited in the STI trenches (122).

FIG. 1F depicts the IC (100) at a subsequent stage of fabrication. Trench surfaces (126) of the STI trenches (122) are oxidized, typically by thermal oxidation, which consumes substrate material. It is within the scope of the instant invention to perform additional processes such as nitridation of the oxidized trench surfaces to improve performance of the circuits fabricated in active regions (130) of the substrate in subsequent operations. An STI fill material (128), typically silicon dioxide, is deposited in the STI trenches (122), commonly by sub-atmospheric chemical vapor deposition (SACVD) or high density plasma (HDP) processes. Subsequent processing steps, such as densification of the STI fill material (128) in an oxidizing ambient at temperatures above 600 C may consume additional substrate material at the trench surfaces (126). Unwanted STI fill material on a top surface of the etched hardmask layer is removed, typically by chemical mechanical polishing (CMP) processes. The STI hardmask material and isolation sidewall spacers are removed, typically by known etching methods involving phosphoric acid.

FIG. 1G depicts the IC (100) after formation of elements of metal oxide semiconductor (MOS) transistors in active regions (130). The STI isolation pad layer is removed from a top surface of the substrate (102), typically by known etching methods involving buffered or dilute hydrofluoric acid. A gate dielectric layer (132), typically silicon dioxide, nitrogen doped silicon dioxide, silicon oxy-nitride, hafnium oxide, layers of silicon dioxide and silicon nitride, or other insulating material, commonly between 1.0 and 2.5 nanometers thick, is formed on a top surface of the active regions (130). An MOS gate layer (134), typically polycrystalline silicon, commonly known as poly silicon, or less commonly, a metallic material, is formed on top surfaces of the gate dielectric layer (132) and STI fill material (128).

The formation of the isolation sidewall spacers to reduce the exposed region for STI trench etching is advantageous because a width of the active regions (130) after formation of MOS transistor elements is desirably increased to a value that is approximately optimum for circuit performance.

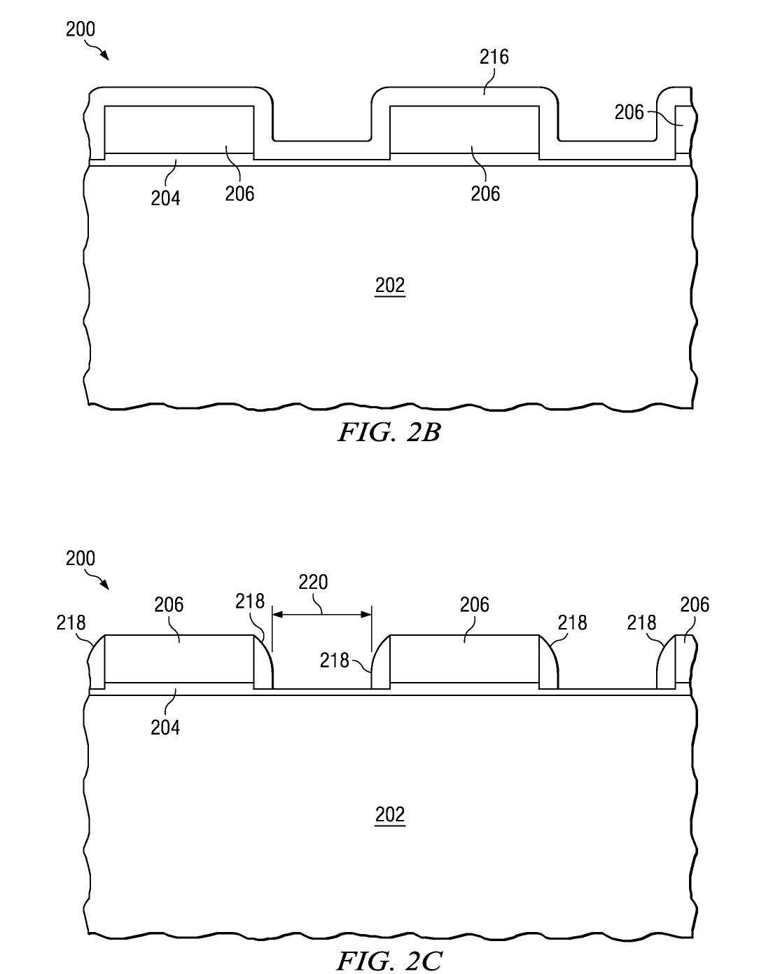

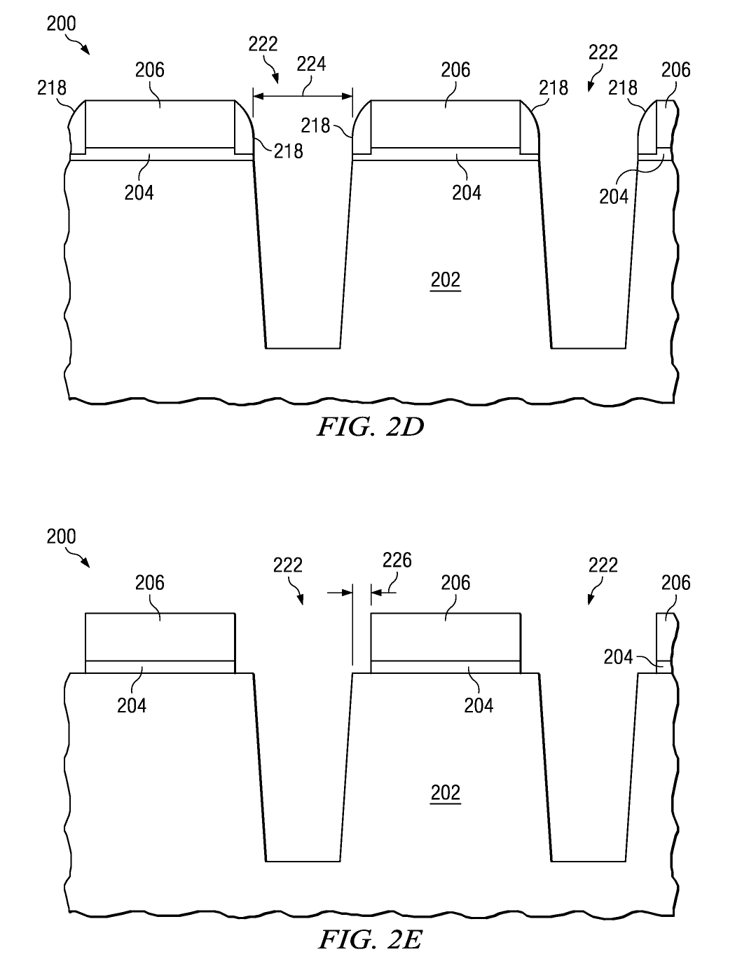

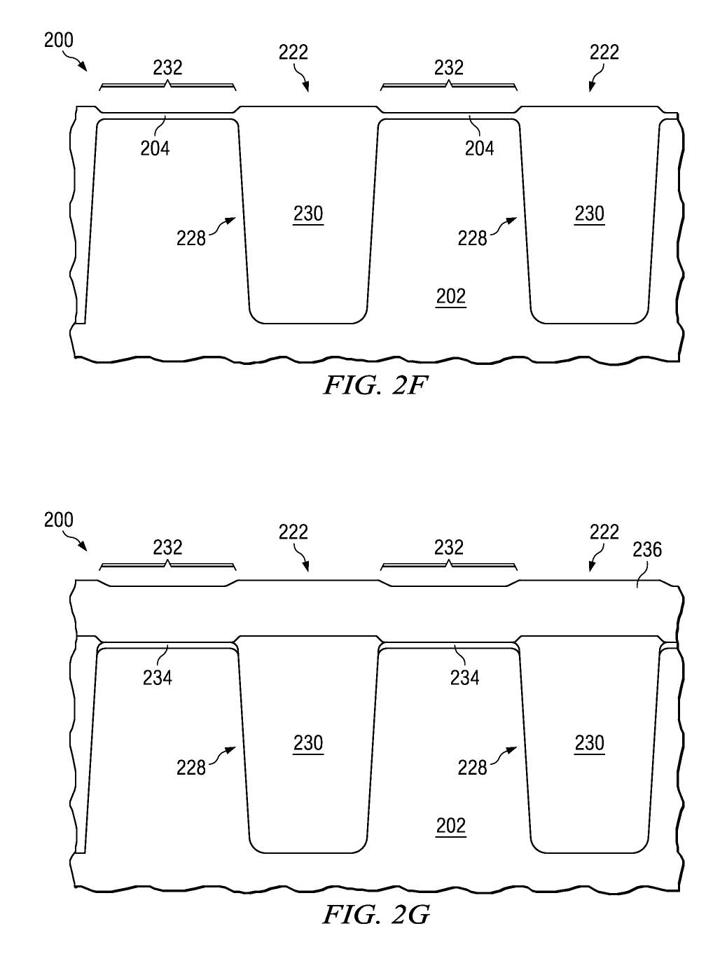

FIG. 2A through FIG. 2G cross-sections of a dense circuit region in an IC with field oxide elements formed by STI processes according to a second embodiment of the instant invention. Referring to FIG. 2A, the IC (200) is fabricated in a semiconductor substrate (202) which has properties as described above in reference to FIG. 1A. An isolation pad layer (204), with properties as described above in reference to FIG. 1A, is formed on a top surface of the substrate (202). An isolation hardmask layer (206), also with properties as described above in reference to FIG. 1A, is formed on a top surface of the isolation pad layer (204). An isolation photoresist pattern (208) is formed on a top surface of the isolation hardmask layer (206) as described above in reference to FIG. 1A, in which a photoresist line width (210) is between 100% and 115% of a space width (212). STI regions (214) for forming trenches in the substrate (202) are exposed by the isolation photoresist pattern (208). Hardmask material in the isolation hardmask layer (206) is removed in the STI regions (214) by known etching methods, as described above in reference to FIG. 1A. A portion of the isolation pad layer (204) may be removed in the STI regions (214) during the hardmask etch process. The isolation photoresist pattern (208) is removed for subsequent processing, as described above in reference to FIG. 1A.

FIG. 2B depicts the IC (200) after deposition of a removable isolation conformal sidewall layer (216) on the top surface and lateral surfaces of the etched isolation hardmask layer (206) and the isolation pad layer (204). In the instant embodiment, the removable isolation conformal sidewall layer (216) is preferably silicon dioxide deposited by known LPCVD or PECVD methods, but is possibly another material that is easily removed in subsequent processing without substantially removing any hardmask material, such as photoresist or other organic material. A thickness of the removable isolation conformal sidewall layer (216) preferably is between 2 and 9 nanometers, and is prescribed by a target thickness of an isolation sidewall spacer formed from the isolation conformal sidewall layer (216) by subsequent processing. For example, to obtain a 5 nanometer thickness of an isolation sidewall spacer, it may be necessary to deposit 6.5 nanometers of sidewall material in the isolation conformal sidewall layer (216).

FIG. 2C depicts the IC (200) after a sidewall anisotropic etch process removes removable isolation conformal sidewall material from a top surface of the etched isolation hardmask layer (206) and a top surface of the isolation pad layer (204) to form removable isolation sidewall spacers (218) on lateral surfaces of the etched isolation hardmask layer (206). The sidewall anisotropic etch process is performed using known RIE methods. A horizontal thickness of the removable isolation sidewall spacers (218) is preferably between 2 and 7 nanometers, and is a function of the thickness of the removable isolation conformal sidewall layer and the sidewall anisotropic etch process. An exposed width (220) of the isolation pad layer (204) is desirably less than the space width (212) of the isolation photoresist pattern (208) described above in reference to FIG. 2A.

FIG. 2D depicts the IC (200) after an STI trench etch process removes substrate material to form STI trenches (222) in the substrate (202). The STI trenches (222) are 125 to 400 nanometers deep, depending on the transistors that will be formed in adjacent substrate regions. An STI trench top width (224) is substantially equal to the exposed width (220) of the isolation pad layer (204) described in reference to FIG. 2C, such that any difference is due to details of the STI trench etch process.

FIG. 2E depicts the IC (200) after removal of the removable isolation sidewall spacers from lateral surfaces of the etched isolation hardmask layer (206) by known etching methods. For example, removable isolation sidewall spacers which are substantially silicon dioxide are preferably removed by immersing the IC (200) in an aqueous solution of dilute or buffered hydrofluoric acid. In an alternate embodiment, etching of silicon dioxide removable isolation sidewall spacers is performed by exposing the IC (200) to a fluorine containing plasma. In another example, removable isolation sidewall spacers which are substantially photoresist or other organic material are preferably removed by a wet clean operation including immersion in a mixture of sulfuric acid and hydrogen peroxide. In a preferred embodiment, substantially no isolation hardmask material is removed during the etching of the removable isolation sidewall spacers. One purpose of the removal of the removable isolation sidewall spacers is to reduce voids in a subsequent STI fill operation in which dielectric material is deposited in the STI trenches (222). An exposed width (226) of the top surface of the substrate (202) adjacent to the etched isolation hardmask layer (206) is substantially the same as the horizontal thickness of the removable isolation sidewall spacers, and is desirably more controllable and reproducible than exposed widths produced by hardmask pullback processes. The exposed width (226) affects a corner profile of the substrate during subsequent processing. Increasing reproducibility of the corner profile improves IC yield and reliability.

FIG. 2F depicts the IC (200) at a subsequent stage of fabrication. Trench surfaces (228) of the STI trenches (222) are oxidized, typically by thermal oxidation, which consumes substrate material. It is within the scope of the instant invention to perform additional processes such as nitridation of the oxidized trench surfaces to improve performance of the circuits fabricated in active regions (232) of the substrate in subsequent operations. An STI fill material (230), typically silicon dioxide, is deposited in the STI trenches (222), commonly by sub-atmospheric chemical vapor deposition (SACVD) or high density plasma (HDP) processes. Subsequent processing steps, such as densification of the STI fill material (230) in an oxidizing ambient at temperatures above 600 C may consume additional substrate material at the trench surfaces (228). Unwanted STI fill material on a top surface of the etched hardmask layer is removed, typically by chemical mechanical polishing (CMP) processes. The STI hardmask material is removed, typically by known etching methods involving phosphoric acid.

FIG. 2G depicts the IC (200) after formation of elements of metal oxide semiconductor (MOS) transistors in active regions (232). The STI isolation pad layer is removed from a top surface of the substrate (202), typically by known etching methods involving buffered or dilute hydrofluoric acid. A gate dielectric layer (234), typically silicon dioxide, nitrogen doped silicon dioxide, silicon oxy-nitride, hafnium oxide, layers of silicon dioxide and silicon nitride, or other insulating material, commonly between 1.0 and 2.5 nanometers thick, is formed on a top surface of the active regions (232). An MOS gate layer (236), typically polycrystalline silicon, commonly known as poly silicon, or less commonly, a metallic material, is formed on top surfaces of the gate dielectric layer (234) and STI fill material (230).

While detailed descriptions of several embodiments of the invention have been given above, various alternatives, modifications, and equivalents will be apparent to those skilled in the art without varying from the spirit of the invention, which is defined by the appended claims.

What is claimed is:

1. A method of forming an element of field oxide by shallow trench isolation (STI) processes, comprising the steps of:
forming an isolation conformal sidewall layer on a top surface and lateral surfaces of an isolation hardmask layer and a top surface of an isolation pad layer under said isolation hardmask layer after said isolation hardmask layer has been etched to expose said isolation pad layer in a region defined for said element of field oxide;
forming isolation sidewall spacers on lateral surfaces of said etched hardmask layer by a process of anisotropic etching of said isolation conformal sidewall layer by which material in said isolation conformal sidewall layer is removed from top surfaces of said etched hardmask layer and said isolation pad layer in said region defined for said element of field oxide;
etching an STI trench in a substrate under said isolation pad layer in said region defined for said element of field oxide, whereby a top width of said STI trench is substantially equal to a lateral separation between said isolation sidewall spacers; and
removing a portion or all of said isolation sidewall spacers prior to depositing STI fill material in said STI trench.

2. The method of claim 1, in which a horizontal thickness of said isolation sidewall spacers is between 2 and 7 nanometers.

3. The method of claim 2, in which:
said etched hardmask layer is comprised of silicon nitride; and
said isolation sidewall spacers are comprised of silicon nitride.

4. The method of claim 2, in which:
said isolation sidewall spacers are comprised of a different material than said etched hardmask layer; and
said step of removing a portion or all of said isolation sidewall spacers does not remove a substantial amount of material from said etched hardmask layer.

5. The method of claim 4, in which said isolation sidewall spacers are comprised of silicon dioxide.

6. A method of forming a metal oxide semiconductor (MOS) transistor adjacent to an element of field oxide formed by STI processes, comprising the steps of:
forming an isolation conformal sidewall layer on a top surface and lateral surfaces of an isolation hardmask layer and a top surface of an isolation pad layer under said isolation hardmask layer after said isolation hardmask layer has been etched to expose said isolation pad layer in a region defined for said element of field oxide adjacent to a region defined for said MOS transistor;
forming isolation sidewall spacers on lateral surfaces of said etched hardmask layer by a process of anisotropic etching of said isolation conformal sidewall layer by which material in said isolation conformal sidewall layer is removed from top surfaces of said etched hardmask layer and said isolation pad layer in said region defined for said element of field oxide; and
etching an STI trench in a substrate under said isolation pad layer in said region defined for said element of field oxide, whereby a top width of said STI trench is substantially equal to a lateral separation between said isolation sidewall spacers.

7. The method of claim 6, further comprising the step of removing a portion or all of said isolation sidewall spacers prior to depositing STI fill material in said STI trench.

8. The method of claim 6, further comprising the steps of:
removing said isolation pad layer in said region defined for said MOS transistor;
forming a gate dielectric layer on a top surface of said substrate in said region defined for said MOS transistor; and
forming an MOS gate material layer on a top surface of said gate dielectric layer.

9. The method of claim 8, in which a horizontal thickness of said isolation sidewall spacers is between 2 and 7 nanometers.

10. The method of claim 9, in which:
said etched hardmask layer is comprised of silicon nitride; and
said isolation sidewall spacers are comprised of silicon nitride.

11. The method of claim 8, in which:
said isolation sidewall spacers are comprised of a different material than said etched hardmask layer; and
said step of removing a portion or all of said isolation sidewall spacers does not remove a substantial amount of material from said etched hardmask layer.

12. The method of claim 11, in which said isolation sidewall spacers are comprised of silicon dioxide.

13. The method of claim 11, in which said isolation sidewall spacers are comprised of photoresist.

14. A method of forming an integrated circuit (IC) containing an MOS transistor between elements of field oxide formed by STI processes, comprising the steps of:
forming an isolation conformal sidewall layer on a top surface and lateral surfaces of an isolation hardmask layer and a top surface of an isolation pad layer under said isolation hardmask layer after said isolation hardmask layer has been etched to expose said isolation pad layer in regions defined for said elements of field oxide adjacent to a region defined for said MOS transistor;
forming isolation sidewall spacers on lateral surfaces of said etched hardmask layer by a process of anisotropic etching of said isolation conformal sidewall layer by which material in said isolation conformal sidewall layer is removed from top surfaces of said etched hardmask layer and said isolation pad layer in said regions defined for said elements of field oxide; and
etching STI trenches in a substrate under said isolation pad layer in said regions defined for said elements of field oxide, whereby a top width of said STI trenches is substantially equal to a lateral separation between said isolation sidewall spacers.

15. The method of claim 14, further comprising the step of removing a portion or all of said isolation sidewall spacers prior to depositing STI fill material in said STI trenches.

16. The method of claim 15, further comprising the steps of:
removing said isolation pad layer in said region defined for said MOS transistor;
forming a gate dielectric layer on a top surface of said substrate in said region defined for said MOS transistor; and
forming an MOS gate material layer on a top surface of said gate dielectric layer.

17. The method of claim 14, in which a horizontal thickness of said isolation sidewall spacers is between 2 and 7 nanometers.

18. The method of claim 17, in which:
said etched hardmask layer is comprised of silicon nitride; and
said isolation sidewall spacers are comprised of silicon nitride.

19. The method of claim 15, in which:
said isolation sidewall spacers are comprised of a different material than said etched hardmask layer; and
said step of removing a portion or all of said isolation sidewall spacers does not remove a substantial amount of material from said etched hardmask layer.

20. The method of claim 19, in which said isolation sidewall spacers are comprised of silicon dioxide.
